(19) United States
(12) Patent Application Publication
(10) Pub. No.: US 2007/0131354 A1
(43) Pub. Date: Jun. 14, 2007

(54) Plasma processing apparatus

(76) Inventors: Kenetsu Yokogawa, Tsurugashima-shi (JP); Tatehito Usui, Kasumigaura-shi (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/353,165

(22) Filed: Feb. 14, 2006

(30) Foreign Application Priority Data
Dec. 13, 2005 (JP) 2005-358679

(51) Int. Cl. H01L 21/306; C23F 1/00

(52) U.S. Cl. 156/345.34; 156/345.24; 156/345.33; 156/345.47

(57) ABSTRACT

The present invention makes an improvement of the sensitivity (accuracy) of monitoring of an amount of etching or remaining amount of etching on the surface of a sample to be processed of a plasma processing apparatus compatible with a long-term continuous stable operation. A transparent body end face of a light introducing section which detects a wavelength of reflected light from the surface of the sample to be processed 3 and a variation in light intensity of each wavelength is placed at a spatial distance equal to or greater than 5 times a mean free path of gas molecules in a vacuum chamber 1 from a boundary of plasma.

The present application is based on and claims priority of Japanese patent application No. 2005-358679 filed on Dec. 13, 2005, the entire contents of which are hereby incorporated by reference.

### BACKGROUND OF THE INVENTION

1. Field of the Invention

The present invention relates to a semiconductor manufacturing apparatus for manufacturing a semiconductor device, and more particularly, to a dry etching technique for etching a semiconductor material such as a silicon and silicon oxide film according to the shape of a mask pattern made of a resist material or the like using plasma.

2. Description of the Related Art

Dry etching introduces a source gas into a vacuum chamber having evacuation means, converts the source gas to plasma through electromagnetic radiation, exposes a sample to be processed to the plasma, applies etching to the surface of the sample to be processed except a masked area and thereby obtains a desired shape. A high-frequency voltage which is different from that used for plasma generation is applied to the sample to be processed, ions are accelerated from plasma at the high-frequency voltage, and input to the surface of the sample to be processed, and it is possible to thereby improve etching efficiency and achieve verticality of the processed shape.

Dry etching judges an end point for judging whether a predetermined amount of etching processing has been completed or not normally through an observation of plasma emission. More specifically, this is done by monitoring an amount of light emission from the material to be etched in plasma or a reaction product of a base material which is exposed when etching is completed. However, with improvement in etching accuracy in recent years and from the standpoint of a cost reduction through simplification of steps, there is a demand for stopping etching processing at some midpoint of a single material or just before finishing the etching instead of finishing the etching with the base material.

It is not possible to judge an end point of etching to meet this demand using the above described method of monitoring light emission from plasma and it is necessary to directly monitor the amount of etching of the material to be etched or the amount of the remaining film. Monitoring of the amount of etching of the material to be etched or the amount of the remaining film is performed by letting in light from plasma reflected on the surface of the sample to be processed or light from an independently provided light source and analyzing an interference pattern of light due to a decrease of the material to be etched on the surface of the sample to be processed (see, for example, Japanese Patent No. 3643540 (Patent Document 1))

An etching apparatus which etches an insulating film material such as a silicon oxide film is provided with a shower plate made of a conductor such as silicon facing the surface of a sample to be processed and applies high-frequency power to the entire conductor including the shower plate to generate plasma. Therefore, it is necessary to place a light introducing section in a conductor electrode section facing the surface of the sample to be processed when the above described amount of etching is calculated through an analysis of an interference pattern of light produced by a decrease of the material to be etched. The light introducing section generally has a structure guiding light to the outside of a vacuum chamber through a transparent body rod of quartz or sapphire or the like and then guiding the light to a light interference pattern analysis section made up of a spectroscope or the like via an optical fibre.

When the above described transparent body of quartz or sapphire which is the light introducing section is directly exposed to the surface of the shower plate made of silicon or the like, wearing and deposition due to accelerated ions from plasma occur on the transparent body rod end face, preventing light from being let in for an extremely short time. A publicly known example shown in Japanese Patent No. 3643540 (Patent Document 1) adopts a structure to solve the problem, forming a plurality of micro pores into which plasma cannot enter in part of the silicon shower plate and placing a transparent body rod on the back thereof. Adopting this structure can extend the light collection life drastically compared to the case where the transparent body rod is directly exposed to plasma. However, even when the structure shown in Japanese Patent No. 3643540 (Patent Document 1) is used, it becomes difficult to let in light after a discharge time of 100 to 200 hours and it is not possible to achieve a sufficient life depending on the degree of volume production of a semiconductor device. Furthermore, it is possible to extend the life of the light introducing section to a certain degree through improvements such as reducing the diameter of micro pores formed in the shower plate and gaining the aspect ratio or the like, but there is a problem that the light quantity decreases and necessary accuracy cannot be secured.

It is an object of the present invention to provide a plasma processing apparatus which judges etching end points by measuring an amount of processing using the above described light interference, provided with means capable of making an extension of life of a light introducing section compatible with securing of an amount of light collection and allowing a long-term stable operation and improvement of processing accuracy through accurate detection of an amount of etching.

The present invention provides a plasma processing apparatus which judges etching end points by measuring an amount of etching of a sample to be processed using light interference on the surface of a sample to be processed, provided with means capable of making an extension of life of a light introducing section compatible with securing of an amount of light collection and allowing a long-term operation and improvement of processing accuracy through accurate detection of an amount of etching.

### SUMMARY OF THE INVENTION

An end face of the light introducing section which lets in interference light from the sample to be processed is placed at a distance from a boundary with plasma equal to or greater than 5 times a mean free path of a gas in a vacuum chamber.

Positioning the end face of the photo-detection section at a distance equal to or greater than 5 times a mean free path of a gas in a vacuum chamber from the boundary with plasma reduces the probability that ions accelerated from plasma may directly arrive at the light introducing section without collision to 1/100 or less. This can drastically reduce wearing of the end face of the light introducing section and extend the life of the light introducing section to a discharge time of 1000 hours or more.

### BRIEF DESCRIPTION OF THE DRAWINGS

FIG. 1 is a basic block diagram of a plasma processing apparatus according to a first embodiment of the present invention;

FIG. 2 illustrates details of the structure of a photo-detection section according to the first embodiment of the present invention;

FIG. 3 illustrates details of the structure of a photo-detection section according to a conventional system;

FIG. 4 illustrates multiples of a mean free path and a proportion of atoms/molecules traveling that distance without collision;

FIG. 5A illustrates details of the structure of a photo-detection section according to a second embodiment of the present invention;

FIG. 5B illustrates details of a modification example of the structure of the photo-detection section according to the second embodiment of the present invention;

FIG. 5C illustrates details of another modification example of the structure of the photo-detection section according to the second embodiment of the present invention; and

FIG. 6 illustrates details of the structure of a photo-detection section according to a third embodiment of the present invention.

### DETAILED DESCRIPTION OF THE PREFERRED EMBODIMENTS

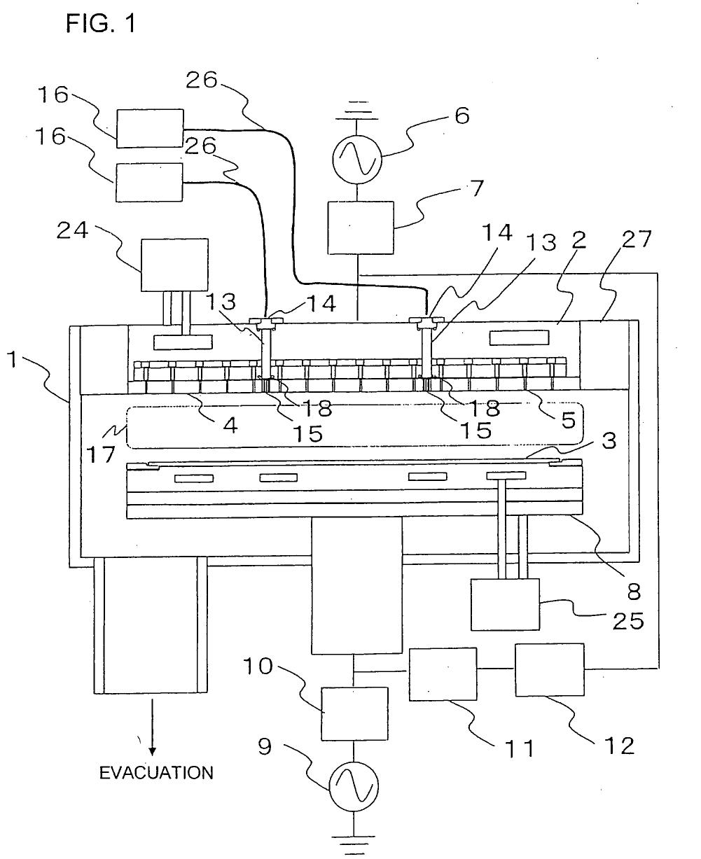

The construction of a first embodiment of a plasma processing apparatus according to the present invention will be explained using FIG. 1.

### Embodiment 1

In the plasma processing apparatus according to the first embodiment, a discharge electrode 2 is placed in a vacuum chamber 1 at a position facing a sample to be processed 3. The discharge electrode 2 is made of a metal such as aluminum. A shower plate 4 made of silicon is placed on the surface of the discharge electrode 2, constituting a structure where a source gas for plasma generation is discharged through micro pores 5 formed over the shower plate 4 into the vacuum chamber 1. A discharge high-frequency power supply 6 is connected to the discharge electrode 2 via a matching circuit 7. A 200 MHz high frequency is used for the discharge high-frequency power supply in this embodiment.

Furthermore, the sample to be processed 3 is placed on a sample setting electrode 8 having an electrostatic adsorption function and held by means of electrostatic adsorption. A high-frequency power supply 9 having a frequency different from the discharge high frequency is connected to the sample setting electrode 8 via a matching circuit 10 so as to apply a high-frequency voltage to the sample to be processed 3. In this embodiment, 4 MHz is used as the frequency of the high-frequency power applied to the sample to be processed. Furthermore, high-frequency power having the same frequency (4 MHz) as the high frequency applied to the sample to be processed 3 with the phase controlled by phase control means 11 is applied to the discharge electrode 2 via a matching circuit 12, superimposed on the discharge high-frequency power.

The high-frequency power applied to the sample to be processed 3 from the high-frequency power supply 9 has the role of accelerating and drawing ions from plasma, can be controlled independently of the discharge high-frequency power supply 6, and can thereby control energy of ions entering the sample to be processed 3 independently of plasma generation. By applying a phase-controlled high-frequency voltage having the same frequency as the frequency applied to the sample to be processed 3 to the discharge electrode 2 from the high-frequency power supply 9, it is possible to suppress increases in the plasma potential and reduce unnecessary wearing due to plasma upon the inner wall of the vacuum chamber 1. Especially, by applying the same frequency yet with a phase 180 degrees different from the high frequency applied to the sample to be processed 3 to the discharge electrode 2, it is possible to suppress energy of ions incident upon the inner wall of the vacuum chamber 1 while controlling energy of ions incident upon the surface of the sample to be processed 3 and the surface of the discharge electrode 2 (surface of the shower plate 4). The application of a phase-controlled high-frequency voltage to the sample to be processed 3 and discharge electrode 2 at a plasma processing apparatus is described, for example, in Japanese Patent Publication No. 2002-184766 (Patent Document 2) or 2003 Proceedings of International Symposium on Dry Process, P43-48 (Non Patent Document 1).

In the plasma processing apparatus of FIG. 1, the discharge electrode 2 is provided with detecting means for detecting reflected light from the surface of the sample to be processed 3 and this detecting means includes a space 13, a light-introducing rod 14 made up of a transparent body of quartz or the like and spectroscopes 16, the shower plate 4 is provided with light-collecting micro pores 15, and the light-introducing rod 14 and spectroscope 16 are connected via an optical fibre 26. The detecting means is means for detecting a wavelength of reflected light from the surface of the sample to be processed 3 and a variation of light intensity of each wavelength. The above described light-introducing rod 14 according to this embodiment may use any one of quartz, sapphire, YAG (yttrium-aluminum-garnet) and yttria crystal (Y₂O₃), and more preferably, any one of sapphire, YAG (yttrium-aluminum-garnet) and yttria crystal (Y₂O₃). Sapphire, YAG or yttria crystal is expensive, yet generally tends to be less sputtered than quartz and expected to have a longer life than quartz.

A thermal medium is supplied to the discharge electrode 2 from a temperature control function 24 and a thermal medium is supplied to the sample setting electrode 8 from a temperature control function 25. Plasma 17 is generated between the shower plate 4 of the discharge electrode and the sample to be processed 3. An insulator 27 is provided between the vacuum chamber 1 and discharge electrode 2 and a seal 18 is provided around the light-collecting micro pores 15 of the shower plate 4.

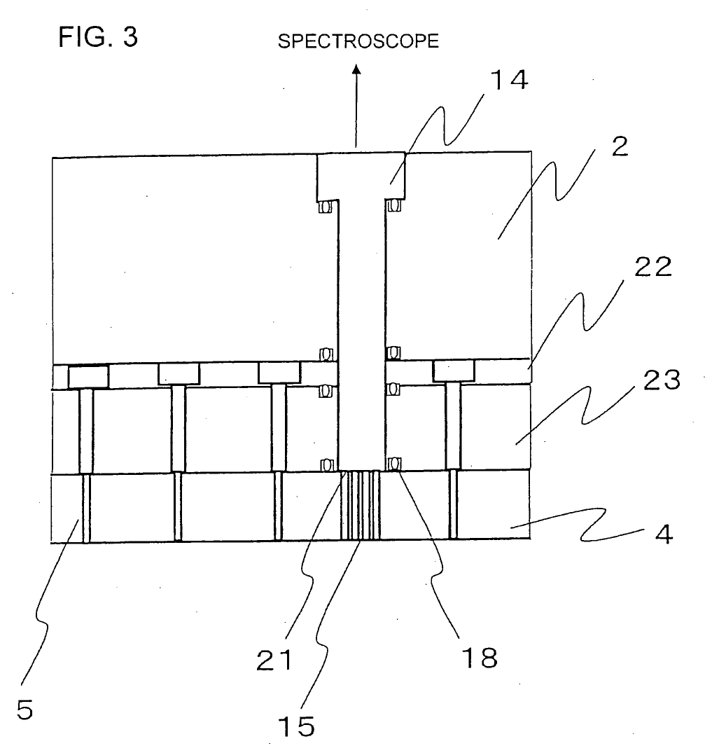

The structure of a conventional light collection section will be explained using FIG. 3. The discharge electrode section is constructed of the discharge electrode 2, a gas diffusion section 22, a gas diffusion passage section 23 and the shower plate 4 stacked one atop another and a gas supplied from a gas supply source which is not shown is diffused by the gas diffusion section 22, passed through the gas diffusion passage section 23 and supplied into the processing chamber through the micro pores 5 provided in the shower plate 4. A space is provided which penetrates the discharge electrode 2, gas diffusion section 22 and gas diffusion passage section 23 and reaches the light-collecting micro pores 15 provided in the shower plate 4, and the light-introducing rod 14 is inserted into this space. An end face 21 of the light-introducing rod 14 is placed in contact with the back of the shower plate 4. In order to prevent the gas from reaching the space through the gas diffusion pores of the gas diffusion section 22 and gas diffusion section 23, seals 18 are provided around the space.

If the light-collecting micropores 15 formed in the shower plate 4 are formed with a diameter smaller than the thickness of a plasma sheath, they have a plasma shielding function, and therefore plasma cannot enter the space. However, ions accelerated by plasma through the light-collecting micropores 15 can reach the space. Therefore, if the light-introducing rod end face 21 for light collection is placed right behind the light-collecting micro pores 15 formed in the shower plate 4, there is a problem that the light-introducing rod end face 21 is etched through ion bombardment and the light collection efficiency decreases in a short time. Since the shower plate 4 normally has a thickness on the order of only 6 to 10 mm, the distance from plasma that can be secured is only 6 to 10 mm right behind the shower plate 4. For example, when processing is performed under a pressure of 2 Pa, there is only a distance approximately 2 to 3 times the mean free path of gas molecules of a plasma generation gas (the mean free path of a gas molecule of the plasma generation gas at 2 Pa is 3 to 4 mm), and therefore a considerable amount of accelerated ions directly reach the light-introducing rod end face 21, which results in a problem that the light-introducing rod end face 21 is worn.

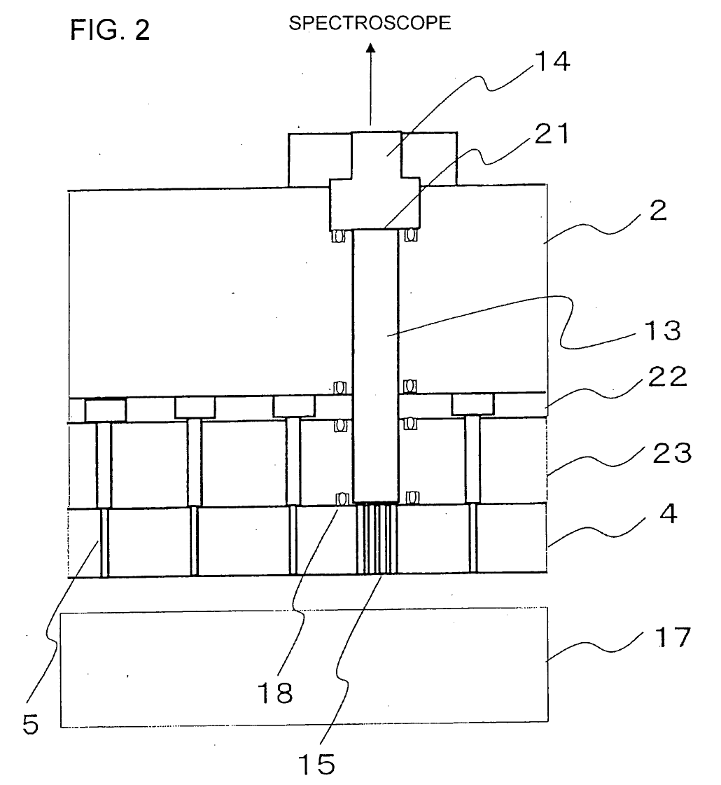

Using FIG. 2, details of the structure in the vicinity of the photo-detection section according to the first embodiment of the present invention will be explained. The light-introducing rod 14 which is the photo-detection section is placed on the back of the shower plate 4 of the discharge electrode 2 via the space 13. This embodiment assumes that the thickness of the shower plate 4 is 10 mm and the length of the space 13 (distance from the back of the shower plate 4 to the light-introducing rod end face 21) is 15 mm. A plurality of light-collecting micro pores 15 having a diameter of 0.5 mm are formed within an area of 10 mm in diameter in the space 13 of the shower plate 4. Reflected light from the sample to be processed 3 is collected by the light-introducing rod 14 via the light-collecting micro pores 15, a variation of interference light caused by a variation of the film thickness on the surface of the sample to be processed 3 is analyzed using the spectroscope 16 and an amount of processing by plasma is detected in real time. The method of detecting the amount of processing with the variation of interference light caused by the variation of the film thickness on the surface of the sample to be processed 3 is described in aforementioned Japanese Patent No. 3643540 (Patent Document 1).

This embodiment places the light-introducing rod end face 21 which collects reflected light from the sample to be processed 3 through the light-collecting micro pores 15 formed in the shower plate 4 and space 13. Furthermore, the length of the space 13 is set so that the distance from the shower plate 4 on the plasma side to the light-introducing rod end face 21 is a distance equal to or greater than 5 times the mean free path of gas molecules under a gas pressure condition in a plasma generation atmosphere inside the vacuum chamber 1. The light-collecting micro pores 15 formed in the shower plate 4 has a plasma shielding function. In this embodiment, the diameter of each of the light-collecting micro pores 15 is 0.4 to 0.5 mm. This prevents plasma from entering the space 13. According to this embodiment, the end face 21 of the light-introducing rod 14 placed at the back of the space 13 formed on the back of the shower plate from the processing chamber is located at a sufficient distance from the plasma 17. That is, in this embodiment, the light-introducing rod end face 21 is placed via the space 13 having a length of 15 mm. Therefore, the distance from the plasma 17 to the light-introducing rod end face 21 is 25 mm, gaining a distance 7 to 8 times the mean free path of gas molecules in an atmosphere of 2 Pa. Thus, the light-introducing rod end face 21 involves almost no ion irradiation, has fewer occasions when the end face is worn, and can thereby obtain a long life.

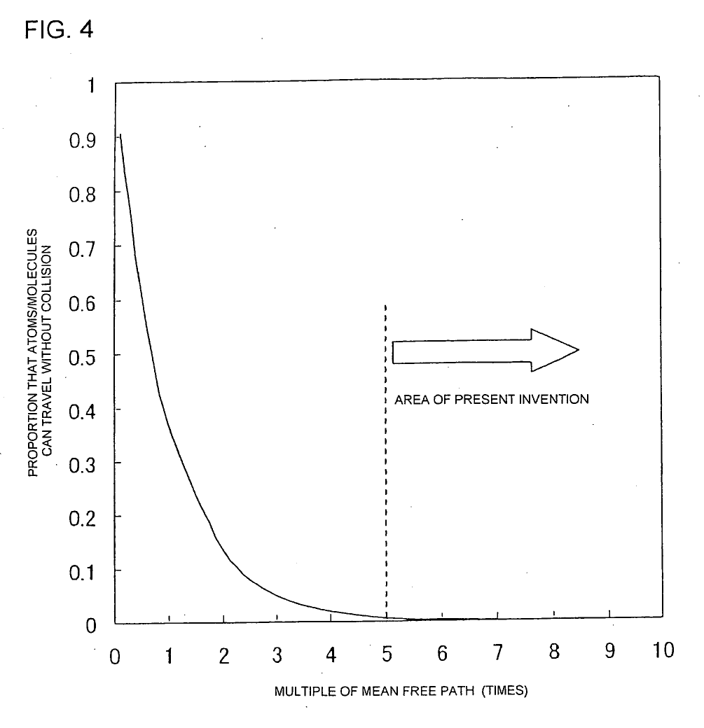

The proportion of molecules/atoms that travel without collision to a multiple of a mean free path is shown using FIG. 4. The proportion of molecules/atoms that travel without collision decreases exponentially with respect to multiples of the mean free path. From FIG. 4, the probability that molecules/atoms can travel a distance approximately 5 times the mean free path falls to or below 1% and most molecules/atoms collide with one another in the vapor phase and lose initial kinetic energy. In distances approximately 7 to 8 times the mean free path, the probability that molecules/atoms can travel without collision falls to or below 0.1%.

Thus, with the construction shown in this embodiment, ions accelerated from the plasma 17 that can reach the light-introducing rod end face 21 without collision falls to or below 0.1%. When the light-introducing rod end face 21 is placed right behind the shower plate 4 which is the conventional method shown in FIG. 3, the mean free path is 2 to 3 times, and therefore according to FIG. 4, the proportion of ions that reach the light-introducing rod end face 21 without collision is approximately 5% to 15%. Therefore, according to the construction of this embodiment, the proportion of ions that reach the light-introducing rod end face 21 without collision is 1/50 to 1/150 compared to the conventional construction and it is possible to drastically extend the life of the light-introducing rod end face 21. The result of an actual evaluation shows that this embodiment secures an enough amount of light collection for a discharge time of 1000 hours, equal to or greater than 5 times that of the conventional system.

Also in the conventional structure of FIG. 3, by letting the source gas of plasma discharged from the shower plate 4 discharge from the light-collecting micro pores 15, it is possible to drastically increase the pressure in the light-collecting micro pores 15 compared to that in the vacuum chamber 1 and even a thickness of the light-collecting micro pores 15 of only approximately 10 mm can have a distance equal to or greater than 5 times the mean free path. However, in this case, since the light-collecting micro pores 15 provided for light collection are formed concentrated on one location, the density of pores is much higher than that of the micro pores 5 for gas discharging, and a large amount of the plasma generation gas is discharged from the light-collecting micro pores 15, deteriorating the uniformity of gas supply by the shower plate 4. Furthermore, depending on the conditions, discharging a large amount of gas from the light-collecting micro pores 15 provokes discharge in the micro pores, which disables detection of reflected light from the wafer. Therefore, the first embodiment provides the seals 18 to prevent the source gas for plasma formation from being discharged from the light-collecting micro pores 15 formed in the shower plate 4. These seals 18 keep the gas pressure inside the light-collecting micro pores 15 and the space 13 to substantially the same level as that in the vacuum chamber 1.

### Embodiment 2

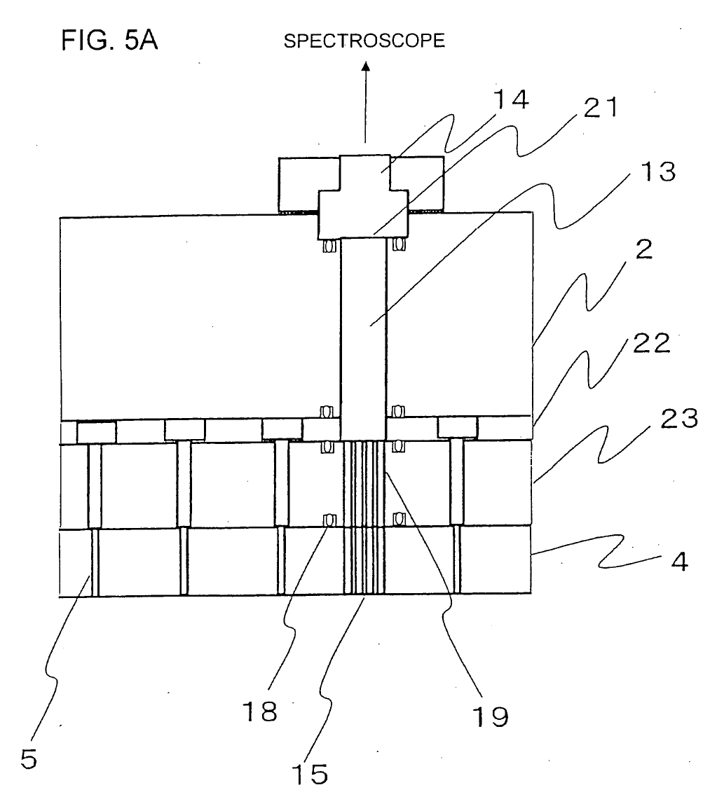

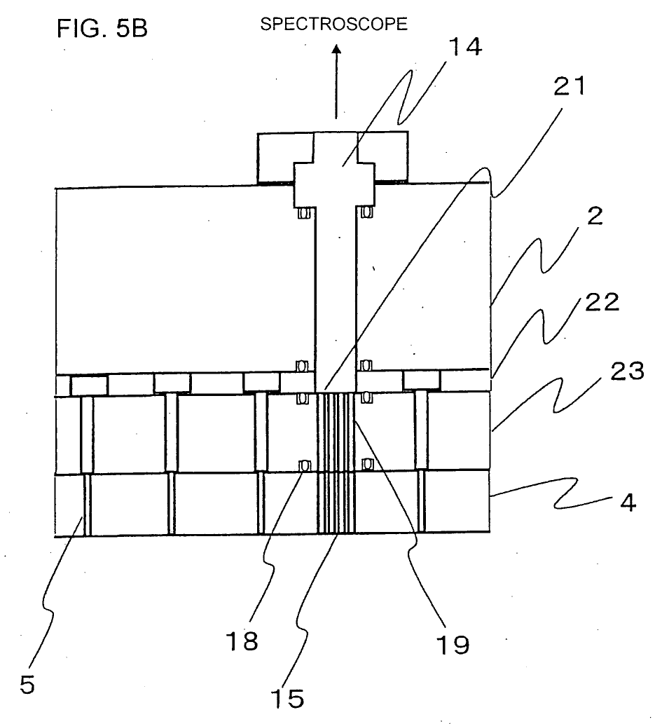

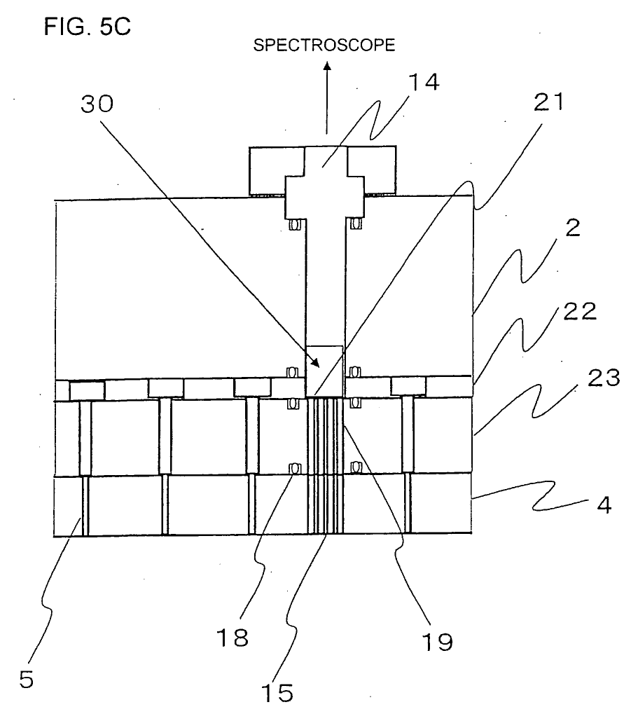

A second embodiment of the present invention will be explained using FIG. 5A. As in the case of FIG. 2 of the first embodiment, FIG. 5A illustrates details of the structure of a photo-detection section formed in a discharge electrode 2. A gas diffusion passage section 23 is provided with a conductor section 19 in FIG. 5A. The conductor section 19 includes similar micro pores aligned with light-collecting micro pores 15 of a shower plate 4 right behind the shower plate 4.

In the structure of FIG. 2 according to the first embodiment shown above, the space 13 is placed right behind the shower plate 4. In the structure of FIG. 2, a discharge high frequency may enter the space 13 and produce discharge inside the space 13 depending on the resistance value of the shower plate 4. Therefore, the second embodiment in FIG. 5A provides the conductor section 19 having a length of several mm (assumed to be 3 mm in this Embodiment 2) right behind the shower plate 4 provided with micro pores similar to those in the shower plate 4 and places a light-introducing rod end face 21 after this via a space 13. This Embodiment 2 produces a loss of light quantity at the conductor section 19 compared to the foregoing Embodiment 1, but setting the length of the conductor section 19 to 1 to 5 mm makes it possible to minimize the amount of loss. The provision of the conductor section 19 completely shuts off the high-frequency power entering the space 13, thus preventing discharge from occurring in the space 13.

FIG. 5B shows a modification example of the second embodiment in the case where the area of the space 13 in the embodiment of FIG. 5A is filled with the light-introducing rod 14 and the light-introducing rod end face 21 is extended up to the top of the gas diffusion passage section 23.

In the embodiment of FIG. 5A, the light-introducing rod end face 21 is placed at a sufficient distance from the plasma boundary, but the space 13 causes the light quantity at the light-introducing rod end face 21 to be decreased. Therefore, in FIG. 5B, the light-introducing rod 14 is placed up to the top of the gas diffusion passage section 23 so as to collect most of light which has passed through the micro pores of the light-collecting micro pores 15 and conductor section 19 of the shower plate 4 and allow the light to transmit up to the top surface of the light-introducing rod 14. If a distance equal to or greater than 5 times the mean free path is secured for the distance from the plasma boundary to the light-introducing rod end face 21 by means of the thickness of the shower plate 4 and the thickness of the conductor of the gas diffusion passage section 23, it is possible to secure a sufficient life of the end face of the light-introducing rod 14.

FIG. 5C shows another modification example of the second embodiment. In the embodiment of FIG. 5B, the single light-introducing rod 14 is extended up to the top of the gas diffusion passage section 23. In contrast, in FIG. 5C, the light-introducing rod 14 consists of two pieces. More specifically, a fore-end section 30 is provided between the light-introducing rod 14 and gas diffusion passage section 23. The material of the fore-end section 30 is basically the same as that of the light-introducing rod 14, yet preferably any one of sapphire, YAG (yttrium-aluminum-garnet) and yttria crystal (Y₂O₃) is used. Though sapphire, YAG or yttria crystal is expensive, it is generally less likely to be sputtered compared to quartz and a longer life is expected than the case where quartz is used.

It is also possible to extend the life of the light-introducing rod 14 even with the construction in FIG. 5B, but there is no change in the fact that the light-introducing rod 14 is a consumable. In the construction in FIG. 5C, the fore-end section 30 is provided as another piece, and therefore in the case of replacement, only the fore-end section 30 needs to be replaced, which improves the easiness of replacement operation and reduces the replacement cost. Therefore, if the light-introducing rod 14 is made of, for example, quartz and the fore-end section 30 is made of any one of sapphire, YAG, yttria crystal, it is possible to realize both cost reduction and extension of life in a well-balanced manner.

### Embodiment 3

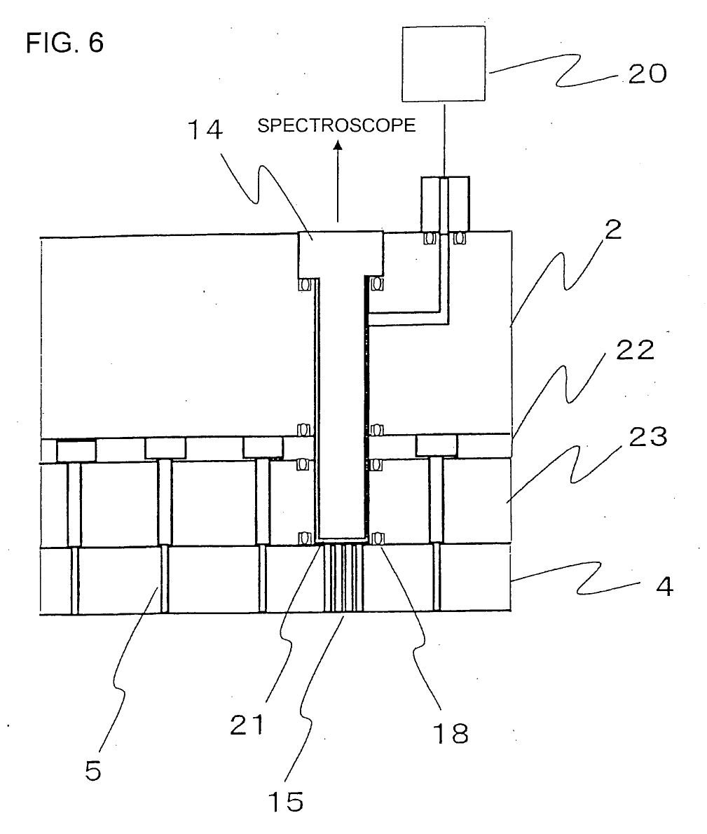

A third embodiment of the present invention will be explained using FIG. 6. FIG. 6 shows details of the structure of a photo-detection section formed in a discharge electrode 2 as in the case of FIG. 2 of the first embodiment. In the embodiment of FIG. 6, a light-introducing rod end face 21 for light collection is placed right behind a shower plate 4, but it is structured in such a way that a gas whose flow rate is controlled independently of the discharge source gas is discharged by gas introducing means 20 from light-collecting micro pores 15 formed in the shower plate 4 into a vacuum chamber 1 via the periphery of a light-introducing rod 14.

By flowing the gas from the gas introducing means 20 into the light-collecting micro pores 15, it is possible to increase the gas pressure in the light-collecting micro pores 15 a great deal and secure a distance equal to or greater than 5 times the mean free path of plasma gas molecules sufficiently with only the thickness of the shower plate 4. In this way, even when the light-introducing rod end face 21 is placed right behind the shower plate 4, the probability that directly accelerated ions constituting plasma may reach is reduced considerably, making it possible to suppress damage to the light-introducing rod end face 21.

By flowing a gas whose flow rate is controlled independently of a source gas for discharge formation through the sealed light-collecting micro pores 15, it is possible to prevent disturbance in the uniformity of supplies of the source gas from the shower plate 4 explained in the foregoing Embodiment 1. Furthermore, using an inert gas such as helium, argon, krypton, xenon or nitrogen as the gas flowing into the light-collecting micro pores 15 by the gas-introducing means 20 eliminates almost all influences on the original plasma processing. The inert gas discharged may be of one kind or may be a mixture of a plurality of kinds of inert gases.

In the above described first embodiment, second embodiment and third embodiment, a coolant for cooling is flown through the discharge electrode 2 and sample setting means 8 and their temperatures are controlled by temperature control functions 24, 25 respectively.

In the above described first embodiment, second embodiment and third embodiment 3, high-frequency power to be applied to the sample to be processed 3 is phase-controlled and applied to the discharge electrode 2, superimposing on the discharge high-frequency power, but equivalent effects of the present invention can also be obtained by applying only discharge high-frequency power to the discharge electrode 2 or applying high-frequency power having a frequency which is different from that applied to the sample to be processed 3, superimposed on the discharge high-frequency power.

What is claimed is:

1. A plasma processing apparatus comprising:
an upper electrode which allows a source gas to flow into a vacuum chamber via a shower plate;
a lower electrode facing the upper electrode, on which a sample to be processed is placed;
a detector which detects light from the surface of the sample to be processed via the shower plate, for generating plasma between the shower plate and the lower electrode and processing the sample to be processed,
wherein the detector comprises a light introducing section made up of a transparent body to which the light is input and a spectroscope which analyzes the light obtained at the light introducing section, and
an end face to which the light at the light introducing section is input is input is placed at a distance equal to or greater than 5 times a mean free path of gas molecules in the vacuum chamber from an end face of the shower plate on the plasma side.

2. The plasma processing apparatus according to claim 1,
wherein the shower plate comprises a plurality of gas through holes through which the source gas passes and light-introducing through holes through which light from the sample to be processed passes,
the upper electrode is a multilayered structure made up of the shower plate, a gas passage member in which a passage for the source gas is formed so as to communicate with the gas through holes of the shower plate and a discharge member connected to a high-frequency power supply, and
the light introducing section is provided for the discharge member.

3. The plasma processing apparatus according to claim 1,
wherein the shower plate comprises a plurality of gas through holes through which the source gas passes and light-introducing through holes through which light from the sample to be processed passes,
the upper electrode is a multilayered structure made up of the shower plate, a gas passage member in which a passage for the source gas is formed so as to communicate with the gas through holes of the shower plate and a discharge member connected to a high-frequency power supply,
the light introducing section is provided for the discharge member, and
a space penetrating the gas passage member and the discharge member is formed between the light-introducing through holes of the shower plate and end face of the light introducing section.

4. The plasma processing apparatus according to claim 1,
wherein the shower plate comprises a plurality of gas through holes through which the source gas passes and light-introducing through holes through which light from the sample to be processed passes,
the upper electrode is a multilayered structure made up of the shower plate, a gas passage member in which a passage for the source gas is formed so as to communicate with the gas through holes of the shower plate and a discharge member connected to a high-frequency power supply,
the light introducing section is provided for the discharge member,
a plurality of the light-introducing through holes of the shower plate are provided for one light introducing section,
the gas passage member is provided with a plurality of light passage pores communicating with the plurality of light-introducing through holes respectively, and
a space penetrating the discharge member is formed between the plurality of light passage pores of the gas passage member and the light introducing section end face.

5. The plasma processing apparatus according to claim 1,
wherein the shower plate comprises a plurality of gas through holes through which the source gas passes and light-introducing through holes through which light from the sample to be processed passes,
the upper electrode is a multilayered structure made up of the shower plate, a gas passage member in which a passage for the source gas is formed so as to communicate with the gas through holes of the shower plate and a discharge member connected to a high-frequency power supply,
the light introducing section is provided for the discharge member,
a plurality of the light-introducing through holes of the shower plate are provided for one light introducing section,
the gas passage member is provided with a plurality of light passage pores communicating with the plurality of light-introducing through holes respectively, and
the light introducing section is placed so as to penetrate the discharge member and the light introducing section end face is placed at a position neighboring the light passage pores.

6. The plasma processing apparatus according to claim 1,
wherein the shower plate comprises a plurality of gas through holes through which the source gas passes and light-introducing through holes through which light from the sample to be processed passes,
the upper electrode is a multilayered structure made up of the shower plate, a gas passage member in which a passage for the source gas is formed so as to communicate with the gas through holes of the shower plate and a discharge member connected to a high-frequency power supply,
the light introducing section is provided for the discharge member,
a plurality of the light-introducing through holes of the shower plate are provided for one light introducing section,
the gas passage member is provided with a plurality of light passage pores communicating with the plurality of light-introducing through holes respectively,
the light introducing section is placed so as to penetrate the discharge member and the light introducing section end face is placed at a position neighboring the light passage pores, and
the light introducing section is made up of two members.

7. The plasma processing apparatus according to claim 1,
wherein the light introducing section is made of any one of quartz, sapphire, YAG (yttrium-aluminum-garnet) and yttria crystal (Y₂O₃).

8. The plasma processing apparatus according to claim 1,
wherein the shower plate comprises a plurality of gas through holes through which the source gas passes and light-introducing through holes through which light from the sample to be processed passes,
the upper electrode is a multilayered structure made up of the shower plate, a gas passage member in which a passage for the source gas is formed so as to communicate with the gas through holes of the shower plate and a discharge member connected to a high-frequency power supply,
the light introducing section is provided for the discharge member,
a plurality of the light-introducing through holes of the shower plate are provided for one light introducing section,
the gas passage member is provided with a plurality of light passage pores communicating with the plurality of light-introducing through holes respectively,
the light introducing section is placed so as to penetrate the discharge member and the light introducing section end face is placed at a position neighboring the light passage pores,
the light introducing section is made up of two members, and
the member of the light introducing section on the shower plate side is made of any one of sapphire, YAG (yttrium-aluminum-garnet) and yttria crystal (Y₂O₃).

9. A plasma processing apparatus comprising:
an upper electrode which allows a source gas to flow into a vacuum chamber via a shower plate;
a lower electrode facing the upper electrode, on which a sample to be processed is placed;
a detector which detects light from the surface of the sample to be processed via the shower plate, for generating plasma between the shower plate and the lower electrode and processing the sample to be processed,
wherein the detector comprises a light introducing section made up of a transparent body to which the light is input and a spectroscope which analyzes the light obtained at the light introducing section,
the shower plate comprises a plurality of gas through holes through which the source gas passes and light-introducing through holes through which light from the sample to be processed passes,
the upper electrode is a multilayered structure made up of the shower plate, a gas passage member in which a passage for the source gas is formed so as to communicate with the gas through holes of the shower plate and a discharge member connected to a high-frequency power supply,
the light introducing section is provided so as to penetrate the gas passage member and the discharge member and the light introducing section end face is placed at a position neighboring the light introducing through holes, and
further comprises gas introducing means for discharging a gas different from the source gas into the light-introducing through holes of the shower plate from the periphery of the light introducing section.

10. The plasma processing apparatus according to claim 9,
wherein the light introducing section is made of quartz or sapphire.

11. The plasma processing apparatus according to claim 9,
wherein the gas introducing means is controlled independently of a flow rate of the source gas and also controlled so that the pressure in the light-introducing through holes of the shower plate is higher than the pressure in the vacuum chamber.

12. The plasma processing apparatus according to claim 9,
wherein the gas introducing means discharges any one or a mixture of two or more kinds of argon, helium, krypton, xenon and nitrogen.

13. A photo detector for a plasma processing apparatus comprising an upper electrode which allows a source gas to flow into a vacuum chamber via a shower plate and a lower electrode facing the upper electrode, on which a sample to be processed is placed, for generating plasma between the shower plate and the lower electrode, and detecting light from the surface of the sample to be processed via the shower plate used in a plasma processing apparatus which processes the sample to be processed, comprising:
a light introducing section made up of a transparent body to which the light is input; and
a spectroscope which analyzes light obtained by the light introducing section,
wherein an end face to which the light at the light introducing section is input is placed at a distance equal to or greater than 5 times a mean free path of gas molecules in the vacuum chamber from an end face of the shower plate on the plasma side.

14. The photo detector apparatus according to claim 13,
wherein the shower plate comprises a plurality of gas through holes through which the source gas passes and light-introducing through holes through which light from the sample to be processed passes,
the upper electrode is a multilayered structure made up of the shower plate, a gas passage member in which a passage for the source gas is formed so as to communicate with the gas through holes of the shower plate and a discharge member connected to a high-frequency power supply, and
the light introducing section is provided for the discharge member.

15. The photo detector apparatus according to claim 13,
wherein the shower plate comprises a plurality of gas through holes through which the source gas passes and light-introducing through holes through which light from the sample to be processed passes,
the upper electrode is a multilayered structure made up of the shower plate, a gas passage member in which a passage for the source gas is formed so as to communicate with the gas through holes of the shower plate and a discharge member connected to a high-frequency power supply,
the light introducing section is provided for the discharge member,
a plurality of the light introducing pores of the shower plate are formed for one light introducing section,
a plurality of light passage pores communicating with the plurality of light-introducing through holes are formed in the gas passage member, and
the light introducing section is placed so as to penetrate the discharge member and light-introducing surface is placed at a position neighboring the light passage pores.

16. The photo detector apparatus according to claim 13,
wherein the shower plate comprises a plurality of gas through holes through which the source gas passes and light-introducing through holes through which light from the sample to be processed passes,
the upper electrode is a multilayered structure made up of the shower plate, a gas passage member in which a passage for the source gas is formed so as to communicate with the gas through holes of the shower plate and a discharge member connected to a high-frequency power supply,
the light introducing section is provided for the discharge member,
a plurality of the light introducing pores of the shower plate are formed for one light introducing section,
a plurality of light passage pores communicating with the plurality of light-introducing through holes are formed in the gas passage member,
the light introducing section is placed so as to penetrate the discharge member and light-introducing surface is placed at a position neighboring the light passage pores, and
the light introducing section is constructed of two members.

17. The photo detector apparatus according to claim 13,
wherein the light introducing section is anyone of quartz, sapphire, YAG (yttrium-aluminum-garnet) and yttria crystal (Y₂O₃).

18. The photo detector apparatus according to claim 13,
wherein the shower plate comprises a plurality of gas through holes through which the source gas passes and light-introducing through holes through which light from the sample to be processed passes,
the upper electrode is a multilayered structure made up of the shower plate, a gas passage member in which a passage for the source gas is formed so as to communicate with the gas through holes of the shower plate and a discharge member connected to a high-frequency power supply,
the light introducing section is provided for the discharge member,
a plurality of the light introducing pores of the shower plate are formed for one light introducing section,
a plurality of light passage pores communicating with the plurality of light-introducing through holes are formed in the gas passage member,
the light introducing section is placed so as to penetrate the discharge member and light-introducing surface is placed at a position neighboring the light passage pores,
the light introducing section is constructed of two members, and
the member of the light introducing section on the shower plate side is made of any one of quartz, sapphire, YAG (yttrium-aluminum-garnet) and yttria crystal (Y₂O₃).
